(19) United States
(12) Patent Application Publication
(10) Pub. No.: US 2008/0213968 A1
(43) Pub. Date: Sep. 4, 2008

(54) METHOD FOR FABRICATING CAPACITOR

(75) Inventors: Cheng-Che Lee, Taichung County (TW); Hui-Ling Chuang, Changhua Hsien (TW); Hsing-Wu Yeh, Hsinchu County (TW)

Correspondence Address: J C PATENTS, INC., 4 VENTURE, SUITE 250, IRVINE, CA, 92618, US

(73) Assignee: PROMOS TECHNOLOGIES INC., Hsinchu (TW)

(21) Appl. No.: 11/766,308

(22) Filed: Jun. 21, 2007

(30) Foreign Application Priority Data
Mar. 2, 2007 (TW) 96107137

(51) Int. Cl. H01L 21/20

(52) U.S. Cl. 438/389; 257/E21.09

(57) ABSTRACT

A method for fabricating a capacitor includes firstly providing a substrate. A doped first dielectric layer and an undoped second dielectric layer are then formed on the substrate sequentially. Next, many trenches are formed in the first and the second dielectric layers. Afterwards, an ion implantation process is performed in the largest space between the adjacent trenches to form an ion-implanted region in a portion of the second dielectric layer in upper parts of the trenches. A wet etching process is then performed to remove a portion of the second dielectric layer in the ion-implanted region and a portion of the first dielectric layer at bottoms of the trenches. Thereafter, a first conductive layer and a capacitor dielectric layer are formed sequentially on surfaces of the trenches. Finally, a second conductive layer is formed in the trenches.

### CROSS-REFERENCE TO RELATED APPLICATION

This application claims the priority benefit of Taiwan application serial no. 96107137, filed on Mar. 2, 2007. All disclosure of the Taiwan application is incorporated herein by reference.

### BACKGROUND OF THE INVENTION

1. Field of the Invention

The present invention relates to a method for fabricating a semiconductor device. More particularly, the present invention relates to a method for fabricating a capacitor.

2. Description of Related Art

A dynamic random access memory (DRAM) stores digital signals through a charge state of a capacitor in a memory cell. The charge storage of the capacitor is determined by a capacitance of the capacitor, and the capacitance is defined according to an area of an electrode, a thickness of a capacitor dielectric layer between an upper electrode and a lower electrode of the capacitor, and a dielectric constant of the capacitor dielectric layer.

With an increase in integrity of semiconductor devices, dimensions of the devices including the capacitor are gradually reduced and so is the capacitance of the capacitor. In a design of integrated circuits (ICs), the capacitance of the capacitor may be effectively increased by extending a surface area of the electrode in the capacitor. In general, the capacitor may be formed in a dual mold oxide (DMO) layer composed of an undoped dielectric layer and a doped dielectric layer through firstly performing a photolithography process and an etching process to form trenches in the DMO layer. A lower electrode, the capacitor dielectric layer and an upper electrode are then formed in the trenches sequentially.

During the formation of the trenches as described above, a bottom width of the trenches is overly narrow in most cases, which is unfavorable to succeeding manufacturing processes. Thus, with a feature that a wet etching rate of the doped dielectric layer exceeds the wet etching rate of the undoped dielectric layer, a portion of the doped dielectric layer at the bottoms of the trenches is removed through carrying out the wet etching process right after the formation of the trenches, and a portion of the doped dielectric layer at the bottoms of the trenches is removed, such that the bottom width of the trenches can be expanded. Thereafter, the fabrication of the capacitor is started. Due to the increase in the bottom width of the trenches after the implementation of the wet etching process, the surface area of the lower electrode is increased as well, and the capacitance of the capacitor is then improved.

However, during the aforesaid wet etching process, since the wet etching process is implemented for a long period of time, the doped dielectric layer at the bottoms of the trenches is apt to be over-etched, leading to an undesirably thin doped dielectric layer at the bottoms between the adjacent trenches. Thereby, after the formation of the capacitor, a short circuit between the lower electrodes of two adjoining capacitors may occur in the underlying doped dielectric layer or on an interface between the undoped dielectric layer and the doped dielectric layer.

Thus, due to advancement of manufacturing technology, a solution to said issues and a way to increase the capacitance and the quality of the capacitor have become one of the most imperative topics in the industry.

### SUMMARY OF THE INVENTION

The present invention is directed to a method for fabricating a capacitor. The method is capable of increasing a surface area of a lower electrode of the capacitor, such that a capacitance of the capacitor can be improved.

The present invention is further directed to a method for fabricating a capacitor. The method is able to increase an upper width and a bottom width of the trenches simultaneously, so as to increase a capacitance of the capacitor and to prevent a short circuit from occurring between the adjacent capacitors.

The present invention provides a method for fabricating a capacitor. The method includes firstly providing a substrate. A doped first dielectric layer and an undoped second dielectric layer are then formed on the substrate sequentially. Next, a plurality of trenches is formed in the first dielectric layer and the second dielectric layer. Afterwards, an ion implantation process is performed in the largest space between the adjacent trenches to form an ion-implanted region in a portion of the second dielectric layer in upper parts of the trenches. A wet etching process is then performed to remove a portion of the second dielectric layer in the ion-implanted region and a portion of the first dielectric layer at bottoms of the trenches. Thereafter, a first conductive layer and a capacitor dielectric layer are formed sequentially on surfaces of the trenches. Finally, a second conductive layer is formed in the trenches.

According to one embodiment of the present invention, the ions implanted through the ion implantation process include boron or phosphorus, for example.

According to one embodiment of the present invention, the concentration of the ions implanted through the ion implantation process ranges from 10¹² atom/cm² to 10¹⁶ atom/cm², for example.

According to one embodiment of the present invention, an implantation angle of the ion implantation process is tan⁻¹(D/L), for example. Here, L represents a depth of the ion-implanted region in the trenches, while D represents a width of the upper parts of the trenches.

According to one embodiment of the present invention, an ion implantation energy used in the ion implantation process ranges from 10 KeV to 2000 KeV, for example.

According to one embodiment of the present invention, the material of the first dielectric layer is phosphosilicate glass (PSG), for example.

According to one embodiment of the present invention, the material of the second dielectric layer is plasma enhanced tetraethylorthosilicate (PE TEOS), for example.

According to one embodiment of the present invention, the material of the first conductive layer is polysilicon or metal, for example.

According to one embodiment of the present invention, the material of the capacitor dielectric layer includes silicon oxide, silicon nitride, or oxide/nitride/oxide (ONO), for example.

According to one embodiment of the present invention, the material of the second conductive layer is polysilicon or metal, for example.

The present invention further provides a method for fabricating a capacitor. The method includes firstly providing a substrate. A doped first dielectric layer and an undoped second dielectric layer are then formed on the substrate sequentially. Next, a plurality of trenches is formed in the first dielectric layer and the second dielectric layer. Afterwards, a mask layer is formed in the trenches. Here, the mask layer exposes a portion of the second dielectric layer in upper parts of the trenches. Thereafter, an overall doping process is performed. Then, the mask layer is removed. After that, a wet etching process is implemented to remove a portion of the doped second dielectric layer and a portion of the first dielectric layer at bottoms of the trenches. A first conductive layer and a capacitor dielectric layer are then formed sequentially on surfaces of the trenches. Finally, a second conductive layer is formed in the trenches.

According to one embodiment of the present invention, the dopant used in the overall doping process includes boron or phosphorus, for example.

According to one embodiment of the present invention, the concentration of the dopant used in the overall doping process ranges from 10¹² atom/cm² to 10¹⁶ atom/cm², for example.

According to one embodiment of the present invention, the material of the first dielectric layer is PSG, for example.

According to one embodiment of the present invention, the material of the second dielectric layer is PE TEOS, for example.

According to one embodiment of the present invention, the material of the first conductive layer is polysilicon or metal, for example.

According to one embodiment of the present invention, the material of the capacitor dielectric layer includes silicon oxide, silicon nitride or ONO, for example.

According to one embodiment of the present invention, the material of the second conductive layer is polysilicon or metal, for example.

Through performing the ion implantation process or the overall doping process on a portion of the second dielectric layer in the upper parts of the trenches, said second dielectric layer may have a larger wet etching rate than the undoped second dielectric layer according to the present invention. Thus, after the implementation of the wet etching process, a portion of the second dielectric layer in the upper parts of the trenches and a portion of the first dielectric layer at the bottoms of the trenches can be simultaneously removed, such that the upper width and the bottom width of the trenches can be expanded at the same time. Thereby, the subsequently-formed lower electrode of the capacitor may have a relatively large surface area, which improves the capacitance of the capacitor and enhances the performance of the devices.

On the other hand, the capacitance is increased by simultaneously expanding the upper width and the bottom width of the trenches according to the present invention. Therefore, the over-etching of the first dielectric layer on account of the requirement for expanding the bottom width of the trenches can be prevented, and the short circuit between the adjacent capacitors can be avoided as well.

In order to make the aforementioned and other objects, features and advantages of the present invention more comprehensible, several embodiments accompanied with figures are described in detail below.

### BRIEF DESCRIPTION OF THE DRAWINGS

FIGS. 1A through 1F are cross-sectional views depicting a process of fabricating a capacitor according to one embodiment of the present invention.

FIG. 2 is a top view depicting an arrangement of trenches according to one embodiment of the present invention.

FIGS. 3A through 3D are cross-sectional views depicting a process of fabricating a capacitor according to another embodiment of the present invention.

### DESCRIPTION OF EMBODIMENTS

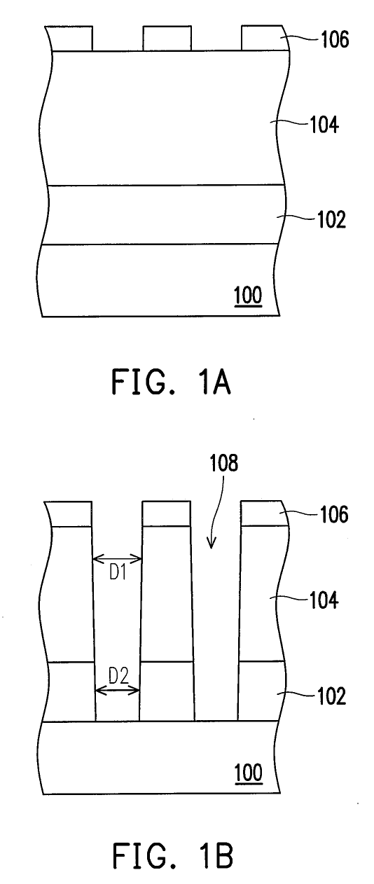

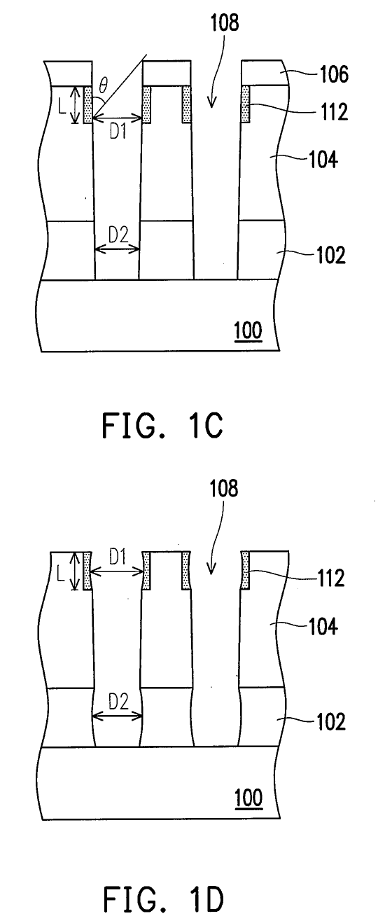

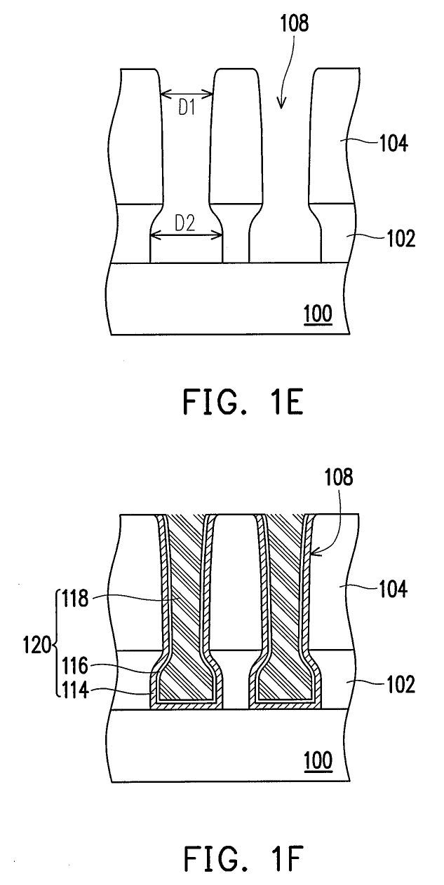

FIGS. 1A through 1F are cross-sectional views depicting a process of fabricating a capacitor according to one embodiment of the present invention.

First, referring to FIG. 1A, a substrate 100 is provided. A conductive region (not shown) or well-known semiconductor devices (not shown) are already formed in the substrate 100, for example. Then, a doped dielectric layer 102 is formed on the substrate 100. The material of the dielectric layer 102 is, for example, PSG or any other appropriate doped dielectric material, and the dielectric layer 102 is formed through performing a chemical vapor deposition (CVD) process, for example. Next, an undoped dielectric layer 104 is formed on the dielectric layer 102. The material of the dielectric layer 104 is, for example, PE TEOS or any other appropriate undoped dielectric material, and the dielectric layer 104 is formed through performing a plasma enhanced CVD process, for example.

Thereafter, referring to FIG. 1A again, a patterned hard mask layer 106 is formed on the dielectric layer 104. The patterned hard mask layer 106 can be, for example but not limited to, made of polysilicon, and the patterned hard mask layer 106 is formed through forming a hard mask layer (not shown) and a patterned photoresist layer (not shown) on the dielectric layer 104 sequentially. Next, the patterned photoresist layer is taken as a mask to remove the exposed hard mask layer, and the patterned photoresist layer is then removed.

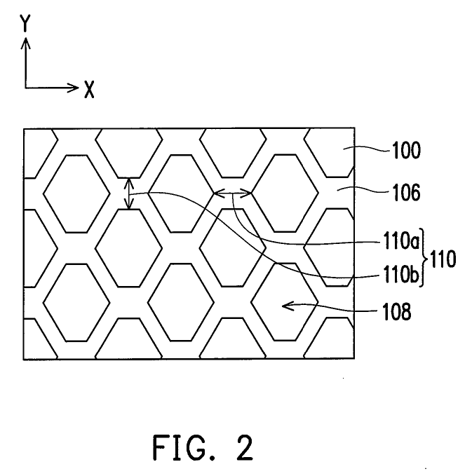

After that, referring to FIG. 1B, an etching process is performed with use of the patterned hard mask layer 106 as the mask, such that trenches 108 are formed in the dielectric layer 102 and the dielectric layer 104. As shown in FIG. 2, the trenches 108 are, for example, interlacedly arranged in the present embodiment. It is certain that the arrangement of the trenches 108 formed in the present invention is not limited to the arrangement described in the present embodiment. Those of ordinary skill in the art can make necessary adjustment based on actual demands. In addition, in a normal manufacturing process, an upper width D1 of the trenches 108 often exceeds a bottom width D2 of the trenches 108 due to a larger depth of the trenches 108 or other manufacturing conditions.

Next, referring to FIGS. 1C and 2 together, an ion implantation process is performed on the largest space 110 between the two adjacent trenches 108, so as to form an ion-implanted region 112 in a portion of the dielectric layer 104 in the upper parts of the trenches 108. The trenches 108 are interlacedly arranged in the present embodiment, and thus the largest space 110 between the two adjacent trenches 108 is, for example, a space 110a in an X direction or another space 110b in a Y direction.

Based on the above, the ions implanted through the ion implantation process include boron or phosphorus, for example, and the concentration of the ions implanted through the ion implantation process ranges from 10¹² atom/cm² to 10¹⁶ atom/cm². Besides, an implantation angle θ of the ion implantation process is, for example, tan⁻¹(D1/L). Here, L represents a depth of the ion-implanted region 112 in the trenches 108, while D1 represents the upper width of the trenches 108. The ion implantation energy used in the ion implantation process ranges from 10 KeV to 2000 KeV, for example. More particularly, since the material of the dielectric layer 102 is, for example, PSG according to the present embodiment, the ions implanted in the ion implantation process are phosphorus, for example. That is to say, it is desirable that the ions implanted in the ion implantation process are the same as a dopant in the dielectric layer 102.

Next, referring to FIG. 1D, an etching back process is carried out to remove the patterned hard mask layer 106. After the removal of the patterned hard mask layer 106, a cleaning process can be alternatively implemented to remove residual impurities after the etching back process is carried out, and thereby an adverse impact on subsequent manufacturing processes can be avoided. A solvent utilized in the cleaning process is tetrahydrofuran (THF), for example. Generally, a wet etching rate of the doped dielectric layer exceeds the wet etching rate of the undoped dielectric layer. Accordingly, the dielectric layer 102 and a portion of the dielectric layer 104 in the ion-implanted region 112 may be slightly worn during the cleaning process.

Afterwards, referring to FIG. 1E, a wet etching process is performed. For example, the wet etching process is a buffer oxide etching (BOE) process with use of a mixture composed of hydrofluoric (HF) acid and ammonium fluoride (NH₄F), and a performing time thereof is approximately 40 seconds. In comparison with the undoped dielectric layer 104 outside the ion-implanted region 112, the dielectric layer 102 and the dielectric layer 104 in the ion-implanted region 112 have higher wet etching rates. Thus, a portion of the dielectric layer 104 in the ion-implanted region 112 and a portion of the dielectric layer 102 at the bottoms of the trenches 108 can be simultaneously removed during the wet etching process. In other words, after the aforesaid wet etching process is implemented, the upper width D1 of the trenches 108 and the bottom width D2 of the trenches 108 are then expanded. Therefore, the lower electrode of the capacitor subsequently formed in the trenches 108 may have an increased surface area, and a capacitance of the capacitor can then be improved.

It should be noted that during the formation of the ion-implanted region 112, the upper width of the trenches 108 can be expanded through adjusting types of the ions, the concentration thereof, the implantation energy, the implantation angle θ, etc after the wet etching process is performed, while a width of the dielectric layer 104 between the upper parts of the adjacent trenches 108 still exceeds a width of the dielectric layer 102 between the bottoms of the adjacent trenches 108. Thereby, a short circuit between the subsequently-formed lower electrodes of the two adjoining capacitors can be prevented from occurring.

Next, referring to FIG. 1F, a conductive layer 114 is formed on surfaces of the trenches 108 as the lower electrode of the capacitor 120. The material of the conductive layer 114 is, for example, polysilison or metal, and the conductive layer 114 is formed by performing the CVD process or a physical vapor deposition (PVD) process. A capacitor dielectric layer 116 is then formed on the conductive layer 114 to isolate a lower electrode of the capacitor 120 from the subsequently-formed upper electrode. The material of the capacitor dielectric layer 116 includes, for example, silicon oxide, silicon nitride or the well-known ONO. As the material of the capacitor dielectric layer 116 is silicon oxide or silicon nitride, the capacitor dielectric layer 116 is formed by performing the CVD process, for example. By contrast, as the material of the capacitor dielectric layer 116 is ONO, the capacitor dielectric layer 116 is formed by firstly implementing a thermal oxidation process to form a first silicon oxide layer. A silicon nitride layer and a second silicon oxide layer are then formed on the first silicon oxide layer in sequence through performing the CVD process. A conductive layer 118 is then formed in the trenches 108 as the upper electrode of the capacitor 120. The material of the conductive layer 118 is, for example, polysilison or metal. The conductive layer 118 is, for example, formed by performing the CVD process or the PVD process, so as to form a conductive material layer (not shown) on the substrate 100. After that, the conductive material layer outside the trenches 108 is removed.

More specifically, the upper width D1 of the trenches 108 and the bottom width D2 of the trenches 108 are simultaneously expanded through implementing the wet etching process; namely, the surface area of the lower electrode formed on the surfaces of the trenches 108 is increased. Thus, the capacitance of the capacitor 120 can be effectively improved, and the short circuit between the lower electrodes of the adjacent capacitors 120 can be prevented from occurring.

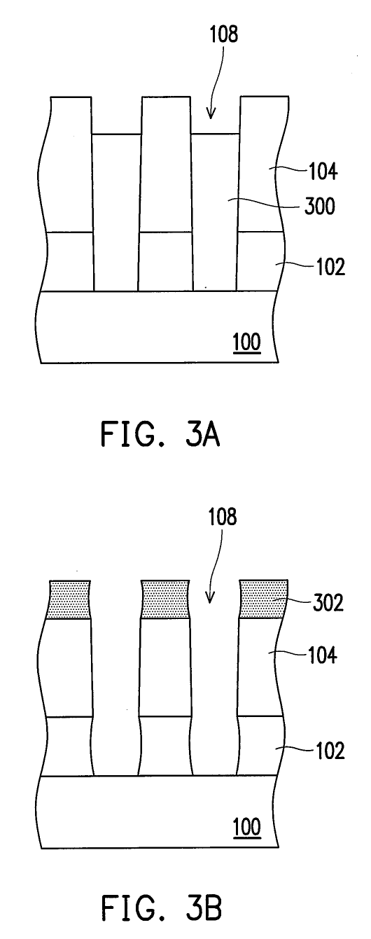

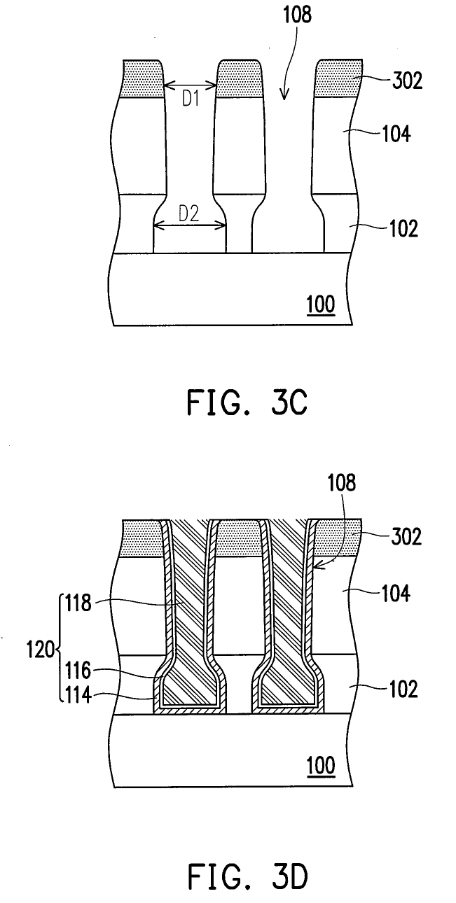

Aside from the aforesaid embodiment, another method for fabricating a capacitor is provided in the present invention as follows. FIGS. 3A through 3D are cross-sectional views depicting a process of fabricating a capacitor according to another embodiment of the present invention. FIG. 3A follows FIG. 1B depicting said embodiment. Besides, identical components in FIGS. 3A through 3D and in FIGS. 1A through 1F use the same reference numbers, and the illustrations thereof are omitted herein.

Referring to FIG. 3A, an etching back process is carried out to remove a patterned hard mask layer 106. Thereafter, a mask layer 300 is formed in the trenches 108. The material of the mask layer 300 is, for example, polysilicon, and the mask layer 300 exposes a portion of a dielectric layer 104 in upper parts of trenches 108.

Next, referring to FIG. 3B, an overall doping process is performed to form a doped region 302 in a portion of the dielectric layer 104, which is located in the upper parts of the trenches 108 and is uncovered by the mask layer 300. The dopant used in the overall doping process includes, for example, boron or phosphorus, and the concentration of the dopant ranges from 10¹² atom/cm² to 10¹⁶ atom/cm² , for example. Since the material of the dielectric layer 102 is, for example, PSG according to the present embodiment, the dopant used in the overall doping process is phosphorus, for example. That is to say, it is desirable that the dopant employed in the overall doping process is the same as the dopant added to the dielectric layer 102.

Afterwards, referring to FIG. 3B again, the mask layer 300 is removed. A cleaning process can then be alternatively implemented to remove residual impurities after the removal of the mask layer 300. A solvent utilized in the cleaning process is THF, for example. The dielectric layer 102 and a portion of the dielectric layer 104 in the doped region 302 have higher wet etching rates than the undoped dielectric layer 104. Accordingly, the dielectric layer 102 and a portion of the dielectric layer 104 in the doped region 302 may be slightly worn during the cleaning process.

After that, referring to FIG. 3C, a wet etching process is performed. The wet etching process uses a BOE etchant composed of HF acid and NH₄F, for example, and the performing time is approximately 40 seconds. During the implementation of the wet etching process, the doped dielectric layer 102 and a portion of the dielectric layer 104 in the doped region 302 has higher wet etching rates than an undoped portion of the dielectric layer 104, and thus the portion of the dielectric layer 104 in the doped region 302 and a portion of the dielectric layer 102 at the bottoms of the trenches 108 are simultaneously removed. In other words, after the wet etching process is carried out, an upper width D1 of the trenches 108 and a bottom width D2 thereof are expanded, and thus a surface area of a lower electrode of a subsequently-formed capacitor can be extended. Thereby, the capacitance of the capacitor is improved.

Likewise, according to the present embodiment, the types of the dopants and the concentration thereof in the doped region 302 can be adjusted during the implementation of the overall doping process, such that a width of the dielectric layer 104 between the upper parts of the two adjacent trenches 108 exceeds a width of the dielectric layer 102 between the bottoms of the two adjacent trenches 108 after the wet etching process is carried out. Thereby, the short circuit between the lower electrodes of the two adjoining capacitors subsequently formed in the trenches 108 can be prevented.

Thereafter, referring to FIG. 3D, a capacitor 120 is then formed in the trenches 108. The capacitor 120 is basically constituted by a conductive layer 114, a capacitor dielectric layer 116 and a conductive layer 118, for example. The conductive layer 114 is used as the lower electrode of the capacitor 120, for example, while the conductive layer 118 is used as an upper electrode of the capacitor 120, for example. The capacitor dielectric layer 116 is employed to isolate the upper electrode of the capacitor 120 from the lower electrode thereof. The method for forming the capacitor 120 is already elaborated hereinbefore, and thus further description will be omitted herein.

In summary, through performing the ion implantation process or the overall doping process on the undoped dielectric layer in the upper parts of the trenches, a portion of the dielectric layer in the ion-implanted region or in the doped region then has a higher wet etching rate than the undoped dielectric layer according to the present invention. Thus, a portion of the doped dielectric layer is removed after the wet etching process is performed. In other words, a portion of the dielectric layer in the upper parts of the trenches and a portion of the dielectric layer at the bottoms of the trenches are simultaneously removed. Thereby, the upper width and the bottom width of the trenches can be expanded at the same time in the present invention, and the surface area of the lower electrode of the subsequently-formed capacitor can be further increased, improving the capacitance of the capacitor and the performance of the device.

On the other hand, the surface area of the lower electrode is increased by simultaneously expanding the upper width and the bottom width of the trenches according to the present invention, and thereby the capacitance of the capacitor is increased. Therefore, the over-etching of the dielectric layer at the bottoms of the trenches can be prevented, and the short circuit between the lower electrodes of the adjacent capacitors is avoided as well.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a capacitor, comprising:
providing a substrate;
forming a doped first dielectric layer and an undoped second dielectric layer on the substrate sequentially;
forming a plurality of trenches in the first dielectric layer and in the second dielectric layer;
performing an ion implantation process in the largest space between the adjacent trenches to form an ion-implanted region in a portion of the second dielectric layer in upper parts of the trenches;
performing a wet etching process to remove a portion of the second dielectric layer in the ion-implanted region and a portion of the first dielectric layer at bottoms of the trenches;
forming a first conductive layer and a capacitor dielectric layer sequentially on surfaces of the trenches; and
forming a second conductive layer in the trenches.

2. The method for fabricating the capacitor as claimed in claim 1, wherein the ions implanted through the ion implantation process comprise boron or phosphorus.

3. The method for fabricating the capacitor as claimed in claim 1, wherein the concentration of the ions implanted through the ion implantation process ranges from 10¹² atom/cm² to 10¹⁶ atom/cm².

4. The method for fabricating the capacitor as claimed in claim 1, wherein the implantation angle of the ion implantation process is tan⁻¹(D/L), L representing a depth of the ion-implanted region in the trenches, D representing a width of the upper parts of the trenches.

5. The method for fabricating the capacitor as claimed in claim 1, wherein the ion implantation energy used in the ion implantation process ranges from 10 Kev to 2000 Kev.

6. The method for fabricating the capacitor as claimed in claim 1, wherein the material of the first dielectric layer comprises phosphosilicate glass (PSG).

7. The method for fabricating the capacitor as claimed in claim 1, wherein the material of the second dielectric layer comprises plasma-enhanced tetraethylorthosilicate (PE TEOS).

8. The method for fabricating the capacitor as claimed in claim 1, wherein the material of the first conductive layer comprises polysilicon or metal.

9. The method for fabricating the capacitor as claimed in claim 1, wherein the material of the capacitor dielectric layer comprises silicon oxide, silicon nitride, or oxide/nitride/oxide (ONO).

10. The method for fabricating the capacitor as claimed in claim 1, wherein the material of the second conductive layer comprises polysilicon or metal.

11. A method for fabricating a capacitor, comprising:
providing a substrate;
forming a doped first dielectric layer and an undoped second dielectric layer on the substrate sequentially;
forming a plurality of trenches in the first dielectric layer and in the second dielectric layer;
forming a mask layer in the trenches, wherein the mask layer exposes a portion of the second dielectric layer in upper parts of the trenches;
performing a overall doping process;
removing the mask layer;
performing a wet etching process to remove a portion of the doped second dielectric layer and a portion of the first dielectric layer at bottoms of the trenches;
forming a first conductive layer and a capacitor dielectric layer sequentially on surfaces of the trenches; and
forming a second conductive layer in the trenches.

12. The method for fabricating the capacitor as claimed in claim 11, wherein the dopant used in the overall doping process comprises boron or phosphorus.

13. The method for fabricating the capacitor as claimed in claim 11, wherein the concentration of the dopant used in the overall doping process ranges from 10¹² atom/cm² to 10¹⁶ atom/cm².

14. The method for fabricating the capacitor as claimed in claim 11, wherein the material of the first dielectric layer comprises PSG.

15. The method for fabricating the capacitor as claimed in claim 11, wherein the material of the second dielectric layer comprises PE TEOS.

16. The method for fabricating the capacitor as claimed in claim 11, wherein the material of the first conductive layer comprises polysilicon or metal.

17. The method for fabricating the capacitor as claimed in claim 11, wherein the material of the capacitor dielectric layer comprises silicon oxide, silicon nitride, or ONO.

18. The method for fabricating the capacitor as claimed in claim 11, wherein the material of the second conductive layer comprises polysilicon or metal.
